(19) United States
(12) Patent Application Publication
(10) Pub. No.: US 2025/0300651 A1
(43) Pub. Date: Sep. 25, 2025

(54) BOOTSTRAP CIRCUIT AND SWITCHING REGULATOR INCLUDING THE SAME

(71) Applicant: ABLIC Inc., Nagano (JP)

(72) Inventor: Kosuke TAKADA, Nagano (JP)

(73) Assignee: ABLIC Inc., Nagano (JP)

(21) Appl. No.: 19/070,480

(22) Filed: Mar. 4, 2025

(30) Foreign Application Priority Data
Mar. 19, 2024 (JP) 2024-043254

(51) Int. Cl. H03K 17/06; H02M 3/158

(52) U.S. Cl. CPC H03K 17/063; H02M 3/158

(57) ABSTRACT

A bootstrap circuit and a switching regulator with a small chip area include: a first NMOS transistor and a second NMOS transistor connected in series between a power supply terminal and a ground terminal; a switch circuit including an input port connected to the first input terminal, an output port, a third NMOS transistor containing a gate, a source connected to the input port of the switch circuit, and a drain connected to the output port of the switch circuit; and a bootstrap capacitor, including a first end connected to the output port of the switch circuit and a second end connected to the output terminal.

### CROSS-REFERENCE TO RELATED APPLICATION

This application claims the priority benefits of Japanese application no. 2024-043254, filed on Mar. 19, 2024. The entirety of the above-mentioned patent application is hereby incorporated by reference herein and made a part of this specification.

### BACKGROUND

### Technical Field

The present invention relates to a bootstrap circuit and a switching regulator including the same.

### Description of Related Art

Generally, bootstrap circuits are used in devices such as switching regulators, and a PMOS transistor is used as a synchronous switch for charging a bootstrap capacitor (for example, refer to Japanese Patent Application Laid-Open No. 2023-62427).

However, in conventional bootstrap circuits, the PMOS transistor used as the synchronous switch has a high on-resistance, resulting in a large chip area.

The present invention provides a bootstrap circuit and a switching regulator with a small chip area.

### SUMMARY

A bootstrap circuit according to an aspect of the present invention includes: a first input terminal; a second input terminal; an output terminal; a first NMOS transistor connected between a power supply terminal and the output terminal; a second NMOS transistor connected between the output terminal and a ground terminal; an inverter which includes an input port connected to the second input terminal and an output port; a depletion type NMOS transistor containing a gate connected to the output port of the inverter and a source connected to the first input terminal; a boost capacitor which includes a first end connected to a drain of the depletion type NMOS transistor and a second end connected to the second input terminal; a third NMOS transistor containing a gate connected to the first end of the boost capacitor, a source connected to the first input terminal, and a drain; and a bootstrap capacitor, which includes a first end connected to the drain of the third NMOS transistor and a second end connected to the output terminal.

A bootstrap circuit according to another aspect of the present invention includes: a first input terminal; a second input terminal; an output terminal; a first NMOS transistor, connected between a power supply terminal and the output terminal; a second NMOS transistor, connected between the output terminal and a ground terminal; a switch circuit including an input port connected to the first input terminal, an output port, a third NMOS transistor containing a gate, a source connected to the input port of the switch circuit, and a drain connected to the output port of the switch circuit, the third NMOS transistor switching between an ON state and OFF state; and a bootstrap capacitor, including a first end connected to the output port of the switch circuit and a second end connected to the output terminal.

According to the bootstrap circuit and the switching regulator including the same, the chip area can be reduced by using an NMOS transistor with low on-resistance as the synchronous switch.

### BRIEF DESCRIPTION OF THE DRAWINGS

FIG. 1 is a circuit diagram illustrating a configuration example of a bootstrap circuit according to an embodiment of the present invention.

FIG. 2 is a circuit diagram illustrating a switching regulator including the bootstrap circuit according to the embodiment.

### DESCRIPTION OF THE EMBODIMENTS

A bootstrap circuit and a switching regulator according to an embodiment of the present invention will be described below based on the drawings.

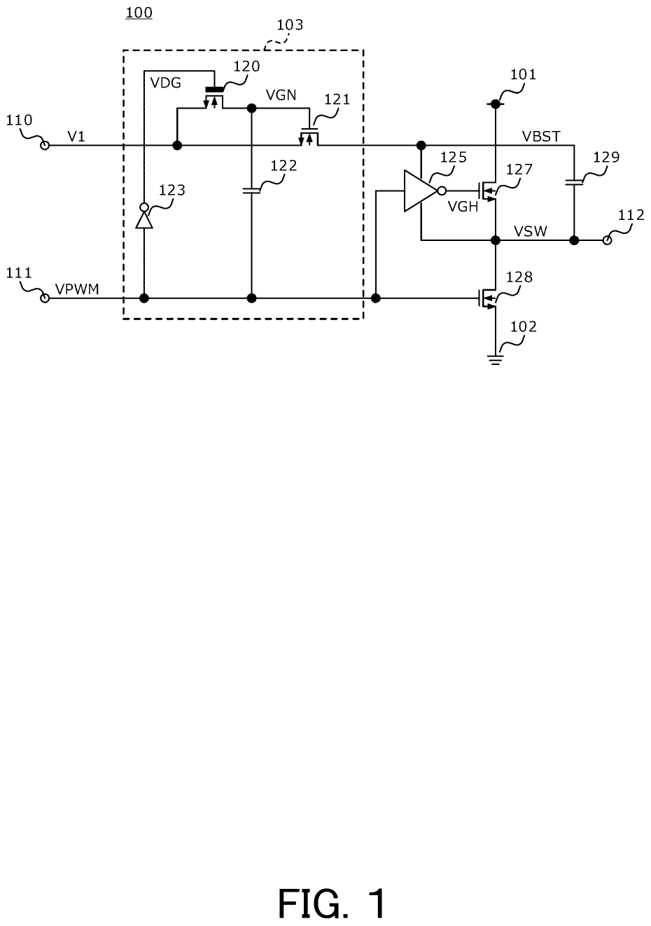

FIG. 1 is a circuit diagram of a bootstrap circuit 100 according to the embodiment.

The bootstrap circuit 100 includes a power supply terminal 101, a ground terminal 102, an input terminal 110 and an input terminal 111 as a first input terminal and a second input terminal, a bootstrap switch circuit 103, an NMOS transistor 127 and an NMOS transistor 128, a capacitor 129 as a bootstrap capacitor, an inverting buffer 125, and an output terminal 112. The bootstrap switch circuit 103 includes a depletion type NMOS transistor 120, an inverter 123, an NMOS transistor 121, and a capacitor 122 as a boost capacitor.

The NMOS transistor 120 contains a gate connected to an output port of the inverter 123, a source connected to the input terminal 110, and a drain connected to a first end of the capacitor 122. The NMOS transistor 121 contains a gate connected to the first end of the capacitor 122, a source connected to the input terminal 110, and a drain connected to a first end of the capacitor 129. The inverter 123 contains an input port connected to the input terminal 111. The capacitor 122 contains the other end connected to the input terminal 111. The inverting buffer 125 contains a first power supply terminal connected to the first end of the capacitor 129, a second power supply terminal connected to the output terminal 112, an input port connected to the input terminal 111, and an output port connected to a gate of the NMOS transistor 127. The NMOS transistor 127 contains a source connected to the output terminal 112 and a drain connected to the power supply terminal 101. The NMOS transistor 128 contains a gate connected to the input terminal 111, a source connected to the ground terminal 102, and a drain connected to the output terminal 112. The capacitor 129 contains a second end connected to the output terminal 112.

Next, the operation of the bootstrap circuit 100 is described.

A predetermined power supply voltage is supplied to the power supply terminal 101. The ground terminal 102, unlike the power supply terminal 101, is supplied with a power supply voltage that serves as a reference for circuit operation, for example, 0V (hereinafter referred to as “ground voltage”).

A signal V1 of a DC voltage is input to the input terminal 110. A signal VPWM of a pulse voltage is applied to the input terminal 111. The bootstrap switch circuit 103 turns the NMOS transistor 121 on and off in synchronization with the signal VPWM. The inverting buffer 125 outputs a signal VGH based on the signal VPWM received, and turns the NMOS transistor 127 on and off. In this case, since a signal VBST is supplied to the first power supply terminal of the inverting buffer 125 and a signal VSW is supplied to the second power supply terminal, the output signal VGH has a high level equivalent to the signal VBST and a low level equivalent to the signal VSW.

The NMOS transistor 127 and the NMOS transistor 128 have respective gate voltages thereof in opposite phases due to the inverting buffer 125, and are alternately turned on and off to output a signal VSW of a pulse voltage from the output terminal 112. The capacitor 129 supplies a voltage between the signal VBST and the signal VSW as the power supply voltage for the inverting buffer 125, herein the signal VBST is charged in the bootstrap operation described later.

Here, for convenience of description, voltages of each of signals are defined. The signal VPWM and a signal VDG have a low level of 0V and a high level of 5V. The signal V1 is a DC voltage of 5V. Additionally, the NMOS transistor 120 is assumed to have a threshold value of approximately −1V.

In the case of the signal VPWM being at a low level (0V), the output signal VDG of the inverter 123 is at a high level (5V). The NMOS transistor 120 is on because the voltage difference between the gate and the source thereof is 0V. Thus, a voltage of a signal VGN is equal to the signal V1 (5V), so the capacitor 122 is charged to 5V. The NMOS transistor 121 is off because the voltage difference between the gate and the source thereof is 0V. The capacitor 129 is charged by the signal VBST with reference to the signal VSW. The inverting buffer 125 is supplied with the voltage (5V) between the signal VBST charged in the capacitor 129 and the signal VSW as the power supply voltage thereof. The NMOS transistor 128 is off because the gate voltage thereof is at a low level (0V). The NMOS transistor 127 is on because the signal VGH of the high level (VBST) is supplied to the gate thereof from the inverting buffer 125. Consequently, the power supply voltage is output from the output terminal 112.

In the case of the signal VPWM being at a high level (5V), the output signal VDG of the inverter 123 is at a low level (0V). The NMOS transistor 120 is off because the source voltage thereof is 5V and the gate voltage thereof is 0V. The signal VGN at one end of the capacitor 122 becomes 10V because the signal VPWM received by the other end is at a high level (5V). In other words, the NMOS transistor 120, the inverter 123, and the capacitor 122 operate as a boost circuit. The NMOS transistor 121 is on because the source voltage thereof is 5V and the gate voltage thereof is 10V. The NMOS transistor 128 is on because the gate voltage thereof is at a high level (5V). The capacitor 129 is charged with the voltage (5V) of the signal V1 from the input terminal 110 through the NMOS transistor 121 and the NMOS transistor 128. The NMOS transistor 127 is off because the signal VGH of the low level (VSW) is supplied to the gate thereof from the inverting buffer 125. Consequently, the ground voltage of 0V is output from the output terminal 112.

As described above, the bootstrap switch circuit 103 generates the signal VGN by boosting the signal V1 using the NMOS transistor 120, the capacitor 122, and the inverter 123 to turn on the NMOS transistor 121. In other words, the NMOS transistor 121 is controlled by the boosted signal VGN, enabling the NMOS transistor 121 to operate as a synchronous switch for charging the capacitor 129.

Thus, the bootstrap circuit 100 may turn the NMOS transistor 127 on and off by supplying the signal VBST and the signal VSW as the power supply for the inverting buffer 125, herein the signal VBST is a floating voltage generated in synchronization with the signal VPWM. Generally, in the case of adjusting the size of a PMOS transistor to have the same on-resistance as an NMOS transistor, the area becomes two to three times larger than the area of the NMOS transistor. The bootstrap circuit 100 of the embodiment may reduce the circuit area by configuring the synchronous switch of the bootstrap switch circuit 103 with the NMOS transistor 121.

Next, the application of the bootstrap circuit 100 of the embodiment will be described.

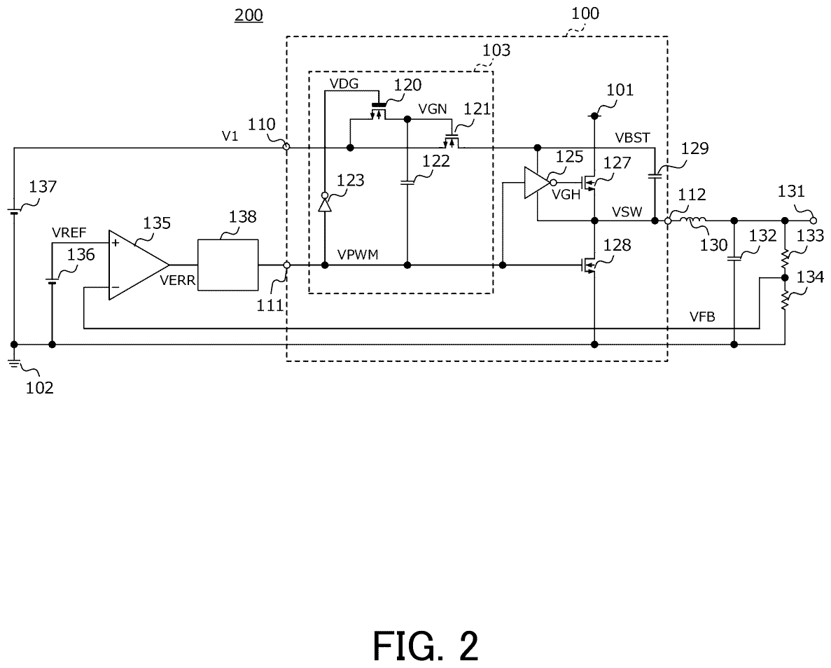

The bootstrap circuit 100 can be used, for example, in a switching regulator as illustrated in FIG. 2.

FIG. 2 is a circuit diagram illustrating a switching regulator 200 including the bootstrap circuit according to the embodiment.

The switching regulator 200 includes a constant voltage circuit 137 which outputs a signal V1 of a direct current voltage, the bootstrap circuit 100, an output terminal 131, a coil 130 and a capacitor 132 that constitute an LC filter, a resistance 133 and a resistance 134 which are voltage divider resistances that output a feedback voltage VFB based on the output voltage of the output terminal 131, a reference voltage circuit 136 which outputs a reference voltage VREF, an error amplifier 135 which outputs a voltage VERR as a result of comparing the reference voltage VREF and the feedback voltage VFB, and a PWM conversion circuit 138 which outputs a signal VPWM based on the voltage VERR.

The bootstrap circuit 100 according to the embodiment is suitable for use in devices such as switching regulators that use NMOS transistors as switching elements, as illustrated in FIG. 2.

The circuit disclosed in the embodiment is an example, and may be implemented in various forms. Furthermore, various omissions, additions, replacements, or modifications may be made without departing from the spirit of the present invention. Such embodiments and their modifications are included in the scope and spirit of the present invention, and are also included in the present invention described in the claims and their equivalents. For example, the voltages of each signal are defined for convenience of explanation and are not limited to these definitions.

What is claimed is:

1. A bootstrap circuit, comprising:
a first input terminal;
a second input terminal;
an output terminal;
a first NMOS transistor, connected between a power supply terminal and the output terminal;
a second NMOS transistor, connected between the output terminal and a ground terminal;
an inverter, including an input port connected to the second input terminal and an output port;
a depletion type NMOS transistor, containing a gate connected to the output port of the inverter and a source connected to the first input terminal;
a boost capacitor, including a first end connected to a drain of the depletion type NMOS transistor and a second end connected to the second input terminal;
a third NMOS transistor, containing a gate connected to the first end of the boost capacitor, a source connected to the first input terminal, and a drain; and
a bootstrap capacitor, including a first end connected to the drain of the third NMOS transistor and a second end connected to the output terminal.

2. The bootstrap circuit according to claim 1, further comprising an inverting buffer, containing an input port connected to the second input terminal, an output port connected to a gate of the first NMOS transistor, a first power supply port, and a second power supply port connected to the output terminal.

3. The bootstrap circuit according to claim 1, wherein
the depletion type NMOS transistor, the boost capacitor, and the inverter constitute a boost circuit, and
the boost circuit is configured to generate a boost voltage based on a first input signal received from the first input terminal and a second input signal received from the second input terminal, and make the third NMOS transistor conductive by the boost voltage.

4. A bootstrap circuit, comprising:
a first input terminal;
a second input terminal;
an output terminal;
a first NMOS transistor, connected between a power supply terminal and the output terminal;
a second NMOS transistor, connected between the output terminal and a ground terminal;
a switch circuit including an input port connected to the first input terminal, an output port, a third NMOS transistor containing a gate, a source connected to the input port of the switch circuit, and a drain connected to the output port of the switch circuit, the third NMOS transistor switching between an ON state and OFF state; and
a bootstrap capacitor, including a first end connected to the output port of the switch circuit and a second end connected to the output terminal.

5. The bootstrap circuit according to claim 4, further comprising an inverting buffer, containing an input port connected to the second input terminal, an output port connected to a gate of the first NMOS transistor, a first power supply port, and a second power supply port connected to the output terminal.

6. The bootstrap circuit according to claim 4, wherein the switch circuit further includes a boost circuit containing:
an input port connected to the input port of the switch circuit, the input port receiving a first voltage supplying from the first input terminal; and
an output port connected to the gate of the third NMOS transistor, the output port outputting a second voltage being higher than the first voltage.

7. The bootstrap circuit according to claim 6, wherein the boost circuit further includes:
a switch, containing a first port connected to the input port of the boost circuit, and a second port connected to the output port of the boost circuit, the switch, switching between ON state and OFF state based upon a voltage supplied from the second input terminal; and
a boost capacitor, containing a first end connected to the second port of the switch, and a second end connected to the second input terminal.

8. The bootstrap circuit according to claim 7, wherein
the switch is configured by a depletion type NMOS transistor containing a source connected to the input port of the boost circuit, and a drain connected to the first end of the boost capacitor, the depletion type NMOS transistor switching between ON state and OFF state based upon a voltage supplied from the second input terminal.

9. The bootstrap circuit according to claim 7, wherein
the switch is configured by a depletion type NMOS transistor containing a gate connected to the second input terminal via an inverter, a source connected to the input port of the boost circuit, and a drain connected to the first end of the boost capacitor.

10. A switching regulator, comprising the bootstrap circuit according to claim 1.

11. A switching regulator, comprising the bootstrap circuit according to claim 4.
